(19) United States
(12) Patent Application Publication
(10) Pub. No.: US 2025/0355175 A1
(43) Pub. Date: Nov. 20, 2025

(54) OPTICAL DEVICE AND METHOD OF MANUFACTURE

(71) Applicant: Taiwan Semiconductor Manufacturing Co., Ltd., Hsinchu (TW)

(72) Inventors: Yu-Hung Lin, Taichung City (TW); Yu-Hao Kuo, Hsinchu County (TW); Chih-Hao Yu, Tainan City (TW); Ren-Fen Tsui, Taipei City (TW); Jui Lin Chao, New Taipei City (TW); Hsing-Kuo Hsia, Jhubei City (TW); Kuo-Chung Yee, Taoyuan City (TW); Chen-Hua Yu, Hsinchu (TW)

(21) Appl. No.: 19/283,727

(22) Filed: Jul. 29, 2025

Related U.S. Application Data
(63) Continuation of application No. 18/593,331, filed on Mar. 1, 2024.
(60) Provisional application No. 63/599,583, filed on Nov. 16, 2023.

(51) Int. Cl. G02B 6/122; G02B 6/12; G02B 6/13

(52) U.S. Cl. CPC G02B 6/122; G02B 6/13; G02B 2006/12102; G02B 2006/12121

(57) ABSTRACT

Optical devices and methods of manufacture are presented in which metallization layers are formed over a first active layer of first optical components, a first opening is formed through the metallization layers, a first semiconductor die is bonded over the metallization layers, and a laser die is bonded over the metallization layers, wherein after the bonding the laser die a first mirror located within the laser die is aligned with a second mirror through the first opening.

### PRIORITY CLAIM AND CROSS-REFERENCE

This application is a continuation of U.S. patent application Ser. No. 18/593,331, filed on Mar. 1, 2024, which application claims the benefit of U.S. Provisional Application No. 63/599,583, filed on Nov. 16, 2023, which applications are hereby incorporated herein by reference.

### BACKGROUND

Electrical signaling and processing is one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4 illustrate formation of an optical interposer, in accordance with some embodiments.

FIG. 5 illustrates a laser die, in accordance with some embodiments.

FIG. 6 illustrates a first semiconductor device, in accordance with some embodiments.

FIGS. 7A-7B illustrate a lens die, in accordance with some embodiments.

FIG. 8 illustrates a bonding of the laser die, the first semiconductor device, and the lens die to the optical interposer, in accordance with some embodiments.

FIG. 9 illustrates an encapsulation process, in accordance with some embodiments.

FIGS. 10A-10B illustrate formation of external connections, in accordance with some embodiments.

FIGS. 11-14 illustrate another embodiment using a gap fill material, in accordance with some embodiments.

FIGS. 15A-15C illustrates additional packages into which the optical device may be incorporated, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be discussed with respect to certain embodiments in which a compact universal photonic engine (COUPE) and laser diode are integrated together by co-package processes. However, the embodiments presented herein are intended to be illustrative and are not intended to limit the embodiments to the discussion presented, as the embodiments may be implemented in a wide variety of devices and methods. All such devices and methods are fully intended to be included within the scope of the embodiments presented herein.

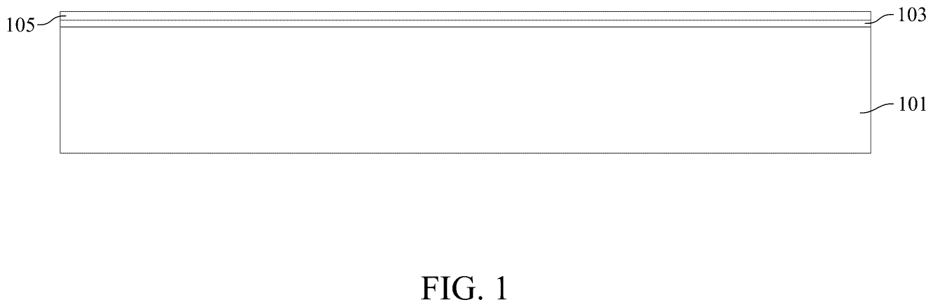

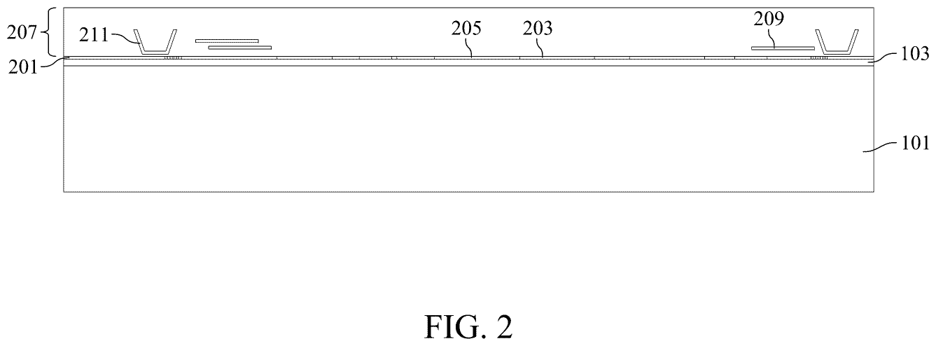

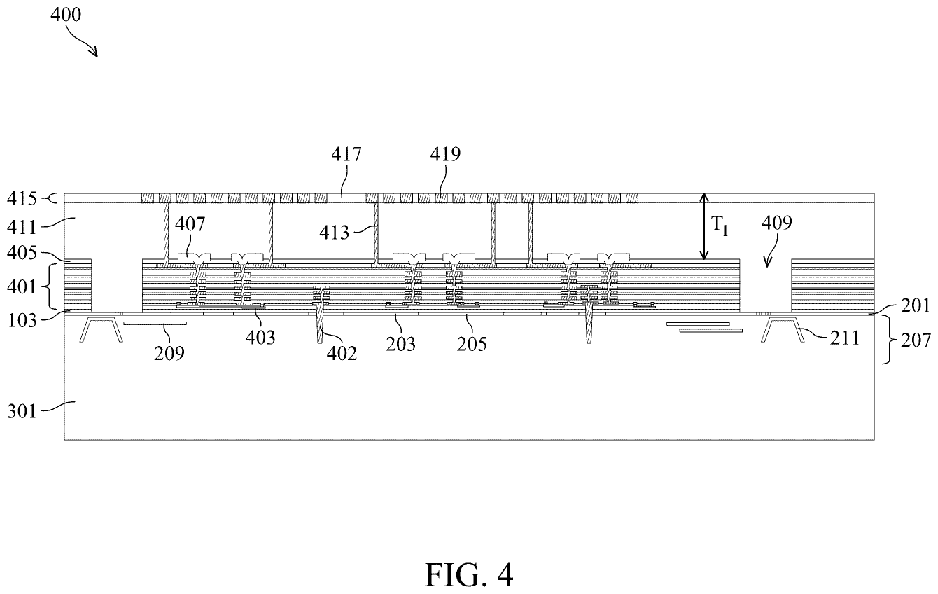

With reference now to FIG. 1, there is illustrated an initial structure of an optical interposer 400 (seen in FIG. 4), in accordance with some embodiments. In the particular embodiment illustrated in FIG. 1, the optical interposer 400 is a photonic integrated circuit (PIC) and comprises at this stage a first substrate 101, a first insulator layer 103, and a layer of material 105 for a first active layer 201 of first optical components 203 (not separately illustrated in FIG. 1 but illustrated and discussed further below with respect to FIG. 2). In an embodiment, at a beginning of the manufacturing process of the optical interposer 400, the first substrate 101, the first insulator layer 103, and the layer of material 105 for the first active layer 201 of first optical components 203 may collectively be part of a silicon-on-insulator (SOI) substrate. Looking first at the first substrate 101, the first substrate 101 may be a semiconductor material such as silicon or germanium, a dielectric material such as glass, or any other suitable material that allows for structural support of overlying devices.

The first insulator layer 103 may be a dielectric layer that separates the first substrate 101 from the overlying first active layer 201 and can additionally, in some embodiments, serve as a portion of cladding material that surrounds the subsequently manufactured first optical components 203 (discussed further below). In an embodiment the first insulator layer 103 may be silicon oxide, silicon nitride, germanium oxide, germanium nitride, combinations of these, or the like, formed using a method such as implantation (e.g., to form a buried oxide (BOX) layer) or else may be deposited onto the first substrate 101 using a deposition method such as chemical vapor deposition, atomic layer deposition, physical vapor deposition, combinations of these, or the like. However, any suitable material and method of manufacture may be used.

The material 105 for the first active layer 201 is initially (prior to patterning) a conformal layer of material that will be used to begin manufacturing the first active layer 201 of the first optical components 203. In an embodiment the material 105 for the first active layer 201 may be a translucent material that can be used as a core material for the desired first optical components 203, such as a semiconductor material such as silicon, germanium, silicon germanium, combinations of these, or the like, while in other embodiments the material 105 for the first active layer 201 may be a dielectric material such as silicon nitride or the like, although in other embodiments the material 105 for the first active layer 201 may be III-V materials, lithium niobate materials, or polymers. In embodiments in which the material 105 of the first active layer 201 is deposited, the material 105 for the first active layer 201 may be deposited using a method such as epitaxial growth, chemical vapor deposition, atomic layer deposition, physical vapor deposition, combinations of these, or the like. In other embodiments in which the first insulator layer 103 is formed using an implantation method, the material 105 of the first active layer 201 may initially be part of the first substrate 101 prior to the implantation process to form the first insulation layer 103. However, any suitable materials and methods of manufacture may be utilized to form the material 105 of the first active layer 201.

FIG. 2 illustrates that, once the material 105 for the first active layer 201 is ready, the first optical components 203 for the first active layer 201 are manufactured using the material 105 for the first active layer 201. In embodiments the first optical components 203 of the first active layer 201 may include such components as optical waveguides (e.g., ridge waveguides, rib waveguides, buried channel waveguides, diffused waveguides, etc.), couplers (e.g., grating couplers, edge couplers that are a narrowed waveguide with a width of between about 1 nm and about 200 nm, etc.), directional couplers, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable first optical components 203 may be used.

To begin forming the first active layer 201 of first optical components 203 from the initial material, the material 105 for the first active layer 201 may be patterned into the desired shapes for the first active layer 201 of first optical components 203. In an embodiment the material 105 for the first active layer 201 may be patterned using, e.g., one or more photolithographic masking and etching processes. However, any suitable method of patterning the material 105 for the first active layer 201 may be utilized. For some of the first optical components 203, such as waveguides or edge couplers, the patterning process may be all or at least most of the manufacturing that is used to form these first optical components 203.

Additionally, for those components that utilize further manufacturing processes, such as optical-to-electrical converters, electrical-to-optical converters, Mach-Zehnder silicon-photonic switches that utilize resistive heating elements, or the like, additional processing may be performed either before or after the patterning of the material for the first active layer 201. For example, implantation processes, additional deposition and patterning processes for different materials (e.g., resistive heating elements, III-V materials for converters), combinations of all of these processes, or the like, can be utilized to help further the manufacturing of the various desired first optical components 203. In a particular embodiment, in some embodiments an epitaxial deposition of a semiconductor material such as germanium (used, e.g., for electricity/optics signal modulation and transversion) may be performed on a patterned portion of the material 105 of the first active layer 201. In such an embodiment the semiconductor material may be epitaxially grown in order to help manufacture, e.g., a photodiode for an optical-to-electrical converter. All such manufacturing processes and all suitable first optical components 203 may be manufactured, and all such combinations are fully intended to be included within the scope of the embodiments.

FIG. 2 also illustrates that, once the individual first optical components 203 of the first active layer 201 have been formed, a second insulator layer 205 may be deposited to cover the first optical components 203 and provide additional cladding material. In an embodiment the second insulator layer 205 may be a dielectric layer that separates the individual components of the first active layer 201 from each other and from the overlying structures and can additionally serve as another portion of cladding material that surrounds the first optical components 203. In an embodiment the second insulator layer 205 may be silicon oxide, silicon nitride, germanium oxide, germanium nitride, combinations of these, or the like, formed using a deposition method such as chemical vapor deposition, atomic layer deposition, physical vapor deposition, combinations of these, or the like. Once the material of the second insulator layer 205 has been deposited, the material may be planarized using, e.g., a chemical mechanical polishing process in order to either planarize a top surface of the second insulator layer 205 (in embodiments in which the second insulator layer 205 is intended to fully cover the first optical components 203) or else planarize the second insulator layer 205 with top surfaces of the first optical components 203. However, any suitable material and method of manufacture may be used.

FIG. 2 also illustrates that, once the first optical components 203 of the first active layer 201 have been manufactured and the second insulator layer 205 has been formed, a second active layer 207 of second optical components 209 may be formed. In an embodiment the second active layer 207 of the second optical components 209 may comprise alternating layers of cladding and core material, the combination of which forms the second optical components 209.

In some embodiments the second optical components 209 of the second active layer 207 may include such components as couplers (e.g., edge couplers, grating couplers, etc.) for connection to outside signals, optical waveguides (e.g., ridge waveguides, rib waveguides, buried channel waveguides, diffused waveguides, etc.), optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable optical components may be used for the one or more second optical components 209.

In an embodiment the one or more second optical components 209 may be formed by initially depositing a material for the one or more second optical components 209. In an embodiment the material for the one or more second optical components 209 may be a dielectric material such as silicon nitride, silicon oxide, combinations of these, or the like, or a semiconductor material such as silicon, deposited using a deposition method such as chemical vapor deposition, atomic layer deposition, physical vapor deposition, combinations of these, or the like. However, any suitable material and any suitable method of deposition may be utilized.

Once the material for the one or more second optical components 209 has been deposited or otherwise formed, the material may be patterned into the desired shapes for the one or more second optical components 209. In an embodiment the material of the one or more second optical components 209 may be patterned using, e.g., one or more photolithographic masking and etching processes. However, any suitable method of patterning the material for the one or more second optical components 209 may be utilized.

For some of the one or more second optical components 209, such as waveguides or edge couplers, the patterning process may be all or at least most manufacturing that is used to form these components. Additionally, for those components that utilize further manufacturing processes, such as Mach-Zehnder silicon-photonic switches that utilize resistive heating elements, additional processing may be performed either before or after the patterning of the material for the one or more second optical components 209. For example, implantation processes, additional deposition and patterning processes for different materials, combinations of all of these processes, or the like, and can be utilized to help further the manufacturing of the various desired one or more second optical components 209. All such manufacturing processes and all suitable one or more second optical components 209 may be manufactured, and all such combinations are fully intended to be included within the scope of the embodiments.

First mirrors 211 are also formed within the second active layer 207 of the second optical components 209. In an embodiment the first mirror 211 may have a taper angle of between about 35° and about 55° and is formed within the second active layer 207 by initially patterning the cladding material to form a recess. In an embodiment the recess may be formed using one or more photolithographic masking and etching processes, such as one or more wet etching processes or dry etching processes. However, any suitable process may be utilized.

Once the recess has been formed, the first mirror 211 may be formed along sidewalls of the recess. In an embodiment the first mirror 211 may be a single layer of a reflective material such as titanium, tantalum, tantalum nitride, aluminum copper, copper, gold, aluminum, titanium nitride, composites of these, combinations of these, or the like, or else may be a multi-layer structure such as a Braggs reflector comprising alternating layers of different materials, such as alternating layers of silicon dioxide and amorphous silicon. The individual materials of the first mirror 211 may be deposited using any suitable methods, such as chemical vapor deposition, physical vapor deposition, plating, combinations of these, or the like, and the individual layers may be then be further patterned using, e.g., a photolithographic masking and etching process (for example, to remove horizontal portions of the deposited materials). However, any suitable materials and methods may be utilized in order to form the first mirror 211 along the sidewalls of the recess.

Additionally, if the formation of the first mirror 211 does not fully fill the recess, the recess may be filled and planarized. In an embodiment the recess may be overfilled with a material similar to the cladding material of the second active layer 207 deposited using a method such as chemical vapor deposition, followed by a planarization process such as a chemical mechanical polishing process. However, any suitable material and any suitable process may be utilized.

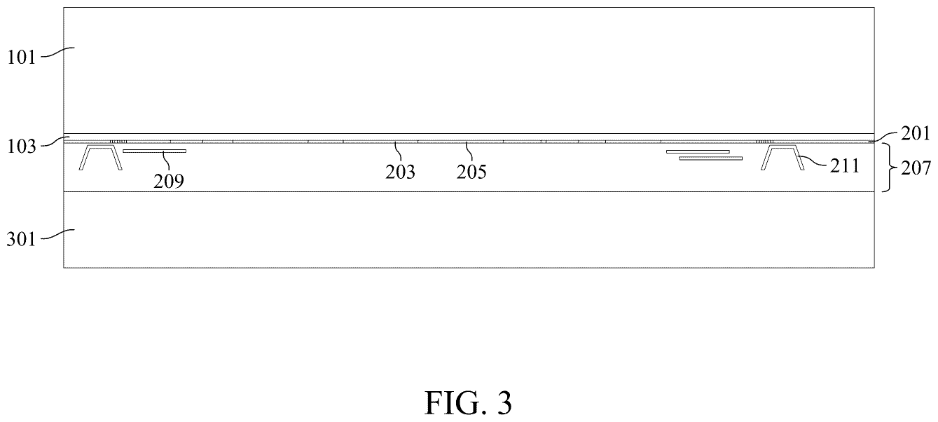

FIG. 3 illustrates an attachment of a carrier substrate 301 to the second active layer 207. In an embodiment the carrier substrate 301 may be a glass wafer, a silicon wafer, a silicon germanium wafer, combinations of these, or the like, and may be bonded using a method such as fusion bonding, dielectric-to-dielectric bonding, combinations of these, or the like. In other embodiments the carrier substrate 301 may be attached using an adhesive layer, such as an ultraviolet tape a pressure sensitive tape, a radiation curable tape, combinations of these, or the like, may also be used. However, any suitable material and method of bonding may be utilized.

FIG. 4 illustrates that, once the carrier substrate 301 has been attached, the first substrate 101 and, optionally, the first insulator layer 103 may be removed, thereby exposing the first active layer 201 of first optical components 203. In an embodiment the first substrate 101 and the first insulator layer 103 may be removed using a planarization process, such as a chemical mechanical polishing process, a grinding process, one or more etching processes, combinations of these, or the like. However, any suitable method may be used in order to remove the first substrate 101 and/or the first insulator layer 103.

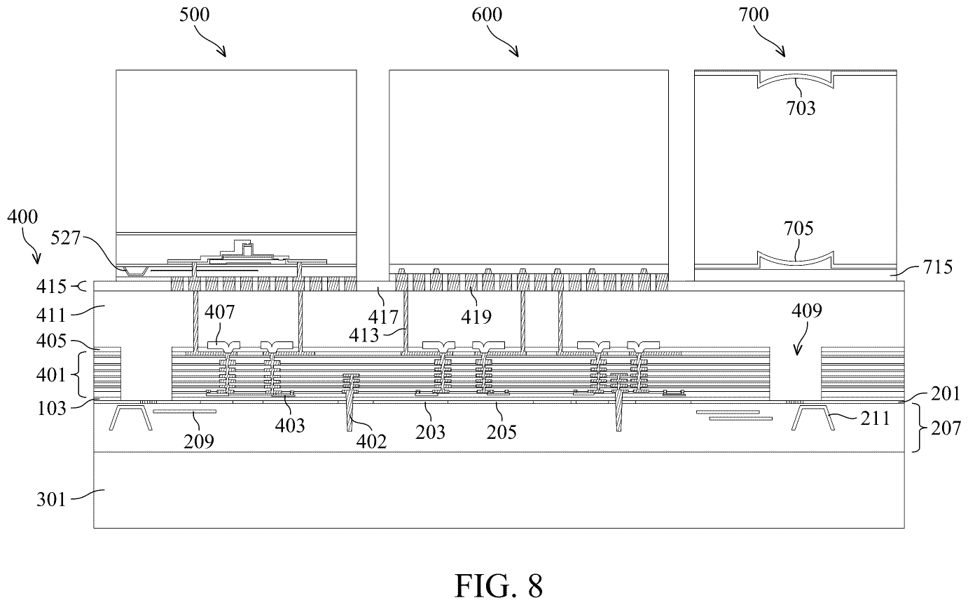

FIG. 4 also illustrates that, once the first substrate 101 has been removed, first metallization layers 401 are formed in order to electrically connect the first active layer 201 of first optical components 203 to control circuitry, to each other, and to subsequently attached devices (not illustrated in FIG. 4 but illustrated and described further below with respect to FIGS. 8-10B). In an embodiment the first metallization layers 401 are formed of alternating layers of dielectric and conductive material and may be formed through any suitable processes (such as deposition, damascene, dual damascene, etc.). In particular embodiments there may be multiple layers of metallization used to interconnect the various first optical components 203, but the precise number of first metallization layers 401 is dependent upon the design of the optical interposer 400.

Additionally, during the manufacture of the first metallization layers 401 (e.g., after the formation of a first layer and before formation of a second layer), first through device vias (TDVs) 402 may be formed. In an embodiment the first through device vias 402 provide a quick passage of power, data, and ground through the optical interposer 400 once formed. In an embodiment the first through device vias 402 may be formed by initially forming through device via openings. The through device via openings may be formed by applying and developing a suitable photoresist (not shown), and removing portions of the first metallization layers 401, the first active layer 201, and the second active layer 207 that are exposed.

Once the through device via openings have been formed, the through device via openings may be lined with a liner. The liner may be, e.g., an oxide formed from tetraethylorthosilicate (TEOS) or silicon nitride, although any suitable dielectric material may alternatively be used. The liner may be formed using a plasma enhanced chemical vapor deposition (PECVD) process, although other suitable processes, such as physical vapor deposition or a thermal process, may also be used.

Once the liner has been formed along the sidewalls and bottom of the through device via openings, a barrier layer (also not independently illustrated) may be formed and the remainder of the through device via openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer (not shown), filling and overfilling the through device via openings. Once the through device via openings have been filled, excess liner, barrier layer, seed layer, and first conductive material outside of the through device via openings may be removed through a planarization process such as chemical mechanical polishing (CMP), although any suitable removal process may be used.

Additionally illustrated in FIG. 4, one or more third optical components 403 may be formed as part of the first metallization layers 401. In an embodiment the one or more third optical components 403 may be formed using similar processes and materials as the second optical components 209. In particular embodiments the one or more third optical components 403 may comprise waveguides comprising silicon nitride along with other devices for converting between optical signals and electric signals. However, any suitable devices formed of any suitable materials may be utilized.

FIG. 4 additionally illustrates that, once the first metallization layers 401 have been formed, a first passivation layer 405 may be deposited to protect the overall structure and first contact pads 407 may be formed. Looking first at the first passivation layer 405, the first passivation layer 405 may be a dielectric material such as silicon nitride, silicon oxide, silicon oxynitride, combinations of these, or the like, deposited using a method such as chemical vapor deposition, physical vapor deposition, atomic layer deposition, combinations of these, or the like. However, any suitable materials and processes may be utilized.

The first contact pads 407 are formed to provide a testing pathway for an electrical connection to the first metallization layers 401 by redistribution lines formed through the first passivation layer 405. In an embodiment the first contact pads 407 may be formed by initially forming an opening in the first passivation layer 405 to expose conductive portions of the underlying first metallization layers 401. Once exposed, a seed layer is deposited, a photolithographic mask is placed and patterned, conductive material such as copper is plated onto the seed layer, the photolithographic mask is removed, and exposed portions of the seed layer are etched away. However, any suitable method or material (such as aluminum deposited and then patterned) may be utilized.

After the first contact pads 407 have been formed, first openings 409 are formed through the first passivation layer 405 and the first metallization layers 401 to provide an optical path through the first metallization layers 401 to the first optical components 203 (e.g., grating couplers) and the first mirrors 211. In an embodiment the first openings 409 may be formed using one or more photolithographic masking and etching processes. However, any suitable processes may be formed.

Additionally, once the first openings 409 have been formed, the first openings 409 are filled and/or overfilled with a first dielectric material 411. In an embodiment the first dielectric material 411 may be a material that is transparent to the wavelength of light that is desired to be used, such as silicon oxide, and may be deposited using a deposition process such as chemical vapor deposition, physical vapor deposition, atomic layer deposition, combinations of these, or the like. However, any suitable material and deposition process may be utilized.

Once the first dielectric material 411 has been deposited, through dielectric vias 413 may be formed through the first dielectric material 411 and the first passivation layer 405. In an embodiment the through dielectric vias 413 may be formed using, e.g., a damascene or dual damascene process. For example, an opening is formed and filled and/or overfilled with a conductive material, and the conductive material is then planarized with the first dielectric material 411. Any suitable process may be utilized.

After the through dielectric vias 413 have been formed a first bonding layer 415 is formed over the first metallization layers 401. In an embodiment, the first bonding layer 415 may be used for a dielectric-to-dielectric and metal-to-metal bond. In accordance with some embodiments, the first bonding layer 415 is formed of a second dielectric material 417 such as silicon oxide, silicon nitride, or the like. The second dielectric material 417 may be deposited using any suitable method, such as CVD, high-density plasma chemical vapor deposition (HDPCVD), PVD, atomic layer deposition (ALD), or the like. However, any suitable materials and deposition processes may be utilized.

Once the second dielectric material 417 has been formed, second openings in the second dielectric material 417 are formed to expose conductive portions of the underlying layers in preparation to form first bond pads 419 within the first bonding layer 415. Once the first openings have been formed within the second dielectric material 417, the first openings may be filled with a seed layer and a plate metal to form the first bond pads 419 within the second dielectric material 417. The seed layer may be blanket deposited over top surfaces of the second dielectric material 417 and the exposed conductive portions of the underlying layers and sidewalls of the second openings. The seed layer may comprise a copper layer. The seed layer may be deposited using processes such as sputtering, evaporation, or plasma-enhanced chemical vapor deposition (PECVD), or the like, depending upon the desired materials. The plate metal may be deposited over the seed layer through a plating process such as electrical or electro-less plating. The plate metal may comprise copper, a copper alloy, or the like. The plate metal may be a fill material. A barrier layer (not separately illustrated) may be blanket deposited over top surfaces of the second dielectric material 417 and sidewalls of the openings and the second openings before the seed layer. The barrier layer may comprise titanium, titanium nitride, tantalum, tantalum nitride, or the like. Following the filling of the first openings, a planarization process, such as a CMP, is performed to remove excess portions of the seed layer and the plate metal, forming the first bond pads 419 within the first bonding layer 415.

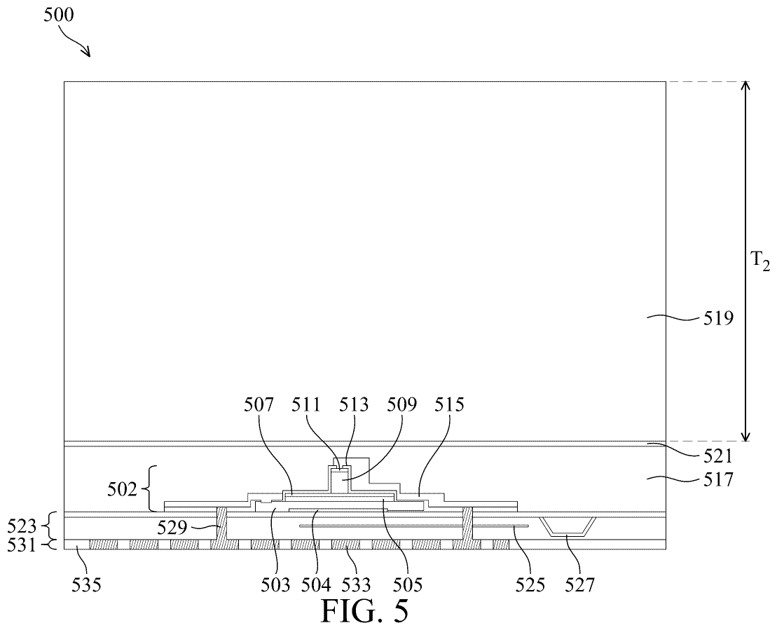

FIG. 5 illustrates a laser die 500 that will be bonded to the first bond layer 415. The laser die 500 is utilized to generate light in order to power the other optical components, and may comprise light generating structures such as a laser diode 502. In particular embodiments the laser diode 502 may be a Fabry-Perot Diode, and may be based on III-V materials, II-VI materials, or any other suitable set of materials.

In an embodiment the formation of the laser die 500 may be initiated by forming a third active layer 523 of fourth optical components 525 on a second substrate (not separately illustrated). Once the third active layer 523 has been formed, a first waveguide 504, a first contact 503, a first buffer layer 505, a first active diode layer 507 comprising multiple quantum wells (MQWs), a second buffer layer (not separately illustrated), a ridge material 509, and a second contact 511 are formed over the second substrate (not separately illustrated). In an embodiment the second substrate may be a material that can be used not only for structural support but also may be used as a seed material for epitaxially growing overlying materials and may be, for example, a 2-inch or 4-inch wafer of material. In particular embodiments in which the laser die 500 utilizes III-V materials to form the desired lasers, the second substrate may be a material such as InP, GaAs, or GaSb, while in embodiments in which the laser die 500 utilizes II-VI materials to form the desired lasers, the second substrate may be a material such as GaAs, CdTe, ZnSe. In still further embodiments, the second substrate may be a sapphire or a semiconductor material. All suitable materials may be utilized.

The first waveguide 504 is formed over the second substrate. In an embodiment the first waveguide 504 comprises a core material such as InP formed, for example, through an epitaxial growth process such as molecular beam epitaxy (MBE), although other processes, such as hydride vapor phase epitaxy (HVPE), liquid phase epitaxy (LPE), or the like, may also be utilized. Once the material for the first waveguide 504 has been formed, the material may be patterned in order to form the desired shape for the first waveguide 504.

The first contact 503 is formed over the first waveguide 504. The first contact 503 forms one part of the laser diode 502 used to emit the desired laser. In an embodiment in which the laser die 500 utilizes III-V compounds, the first contact 503 is a compound such as InP, GaN, InN, AlN, AlxGa(1-x)N, AlxIn(1-x)N, AlxInyGa(1-x-y)N, combinations thereof, or the like. Additionally, in embodiments in which the laser die 500 utilizes II-VI compounds, the first contact 503 may still use a III-V material such as GaAs, InP, GaSb, combinations of these, or the like.

Additionally, in order to help form the laser diode 502 (e.g., the n-p diode) to generate the desired laser, the first contact 503 may be doped with a dopant. In embodiments in which the first contact 503 is desired to have an n-type conductivity, the first contact 503 may be doped with an n-type dopant such as phosphorus, arsenic, antimony, bismuth, lithium, combinations of these, or the like. In other embodiments in which the first contact 503 is desired to have a p-type conductivity, the first contact 503 may be doped with p-type dopants such as boron, aluminum, gallium, indium, combinations of these, or the like. However, any suitable dopants may be utilized.

In some embodiments the first contact 503 is formed, for example, through an epitaxial growth process such as molecular beam epitaxy (MBE), although other processes, such as hydride vapor phase epitaxy (HVPE), liquid phase epitaxy (LPE), or the like, may also be utilized. The first contact 503 is preferably doped in situ during formation, although other processes, such as ion implantation or diffusion may be utilized.

The first buffer layer 505 is formed over the first contact 503 and is utilized in order to help the epitaxial growth of overlying layers (e.g., the first active diode layer 507) transition from the material of the first contact 503 to the material of the overlying layer. In an embodiment in which the laser die 500 utilizes III-V compounds, the first buffer layer 505 is a compound such as InGaAsP, InGaAlAs, InGaAs, combinations thereof, or the like. Additionally, in embodiments in which the laser die 500 utilizes II-VI compounds, the first buffer layer 505 may be a II-VI material such as BeMgZnSe, BeZnCdSe, BeTe, combinations of these, or the like. Additionally, the first buffer layer 505 may be deposited using an epitaxial growth process such as molecular beam epitaxy (MBE), although other processes, such as hydride vapor phase epitaxy (HVPE), liquid phase epitaxy (LPE), or the like, may also be utilized, and may be doped in a similar fashion as the first contact 503. However, any suitable material and any suitable method of deposition may be utilized.

The first active diode layer 507 is formed over the first buffer layer 505. The first active diode layer 507 is designed, among other things, to control the generation of light to desired wavelengths. For example, by adjusting and controlling the proportional composition of the elements in the first active diode layer 507, the bandgap of the materials in the first active diode layer 507 may be adjusted, thereby adjusting the wavelength of light that will eventually be emitted.

The first active diode layer 507 comprises multiple quantum wells (MQW). MQW structures in the first active diode layer 507 in embodiments which utilized III-V materials may comprise, for example, layers of InAlGaAs, InGaN, GaN, AlxInyGa(1-x-y)N (where 0<=x<=1), or the like, while in embodiments which utilize II-VI based materials, the first active diode layer 507 may comprise materials such as BeZnCdSe. The first active diode layer 507 may comprise any number of quantum wells, such as 5 to 20 quantum wells, for example. The MQWs are preferably epitaxially grown using the first buffer layer 505 as a nucleation layer using metal organic chemical vapor deposition (MOCVD), although other processes, such as MBE, HVPE, LPE, or the like, may also be utilized.

The second buffer layer is optionally formed over the first active diode layer 507 and is utilized in order to help the epitaxial growth of overlying layers (e.g., the ridge material 509) transition from the material of the first active diode layer 507 to the material of the overlying layer. In an embodiment in which the laser die 500 utilizes III-V compounds, the second buffer layer is a compound such as InGaAsP, InGaAlAs, InGaAs, combinations thereof, or the like. Additionally, in embodiments in which the laser die 500 utilizes II-VI compounds, the second buffer layer may be a II-VI material such as BeMgZnSe, BeZnCdSe, BeTe, combinations of these, or the like. Additionally, the second buffer layer may be deposited using an epitaxial growth process such as molecular beam epitaxy (MBE), although other processes, such as hydride vapor phase epitaxy (HVPE), liquid phase epitaxy (LPE), or the like, may also be utilized, and may be doped in an opposite fashion from the first contact 503, such as by being doped to a p-type conductivity when the first contact 503 is doped to an n-type conductivity. However, any suitable material and any suitable method of deposition may be utilized.

The ridge material 509 is formed to help assist in the epitaxial growth of an overlying layer (e.g., the second contact 511) transition from the material of the second buffer layer to the material of the overlying layer. In an embodiment in which the laser die 500 utilizes III-V compounds, the ridge material 509 is a compound such as InP or the like. Additionally, in embodiments in which the laser die 500 utilizes II-VI compounds, the ridge material 509 may be a II-VI material such as BeMgZnSe, BeZnCdSe, BeTe, combinations of these, or the like. Additionally, the ridge material 509 may be doped using dopants of an opposite conductivity than the first contact 503, such as by being doped to a p-type conductivity when the first contact 503 is doped to an n-type conductivity. The ridge material 509 may one or more layers and may be deposited using an epitaxial growth process such as molecular beam epitaxy (MBE), although other processes, such as hydride vapor phase epitaxy (HVPE), liquid phase epitaxy (LPE), or the like, may also be utilized. However, any suitable material and any suitable method of deposition may be utilized.

The second contact 511 is formed over the ridge material 509. The second contact 511 forms the second part of the laser diode 502 used to emit light in conjunction with the first contact 503. In an embodiment in which the laser die 500 is based on III-V materials, the second contact 511 comprises a group III-V compound such as InAlAs, GaN, InN, AlN, AlxGa(1-x)N, AlxIn(1-x)N, AlxInyGa(1-x-y)N, combinations thereof, or the like, doped with a dopant of a second conductivity type (e.g., p-GaN) opposite the first conductivity type in the first contact 503. In another embodiment in which the laser die 500 is based on II-VI materials, the second contact 511 may be a II-VI material such as BeTe, BeMgZnSe, BeZnCdSe, combinations of these, or the like. The second contact layer 511 may be formed, for example, through an epitaxial growth process such as MOCVD. However, any suitable materials and any other suitable processes, such as HVPE, LPE, MBE, or the like, may also be utilized.

Once the second contact 511, the ridge material 509, the second buffer layer, the first active diode layer 507, the first buffer layer 505, and the first contact 503 have been formed, the second contact 511, the ridge material 509, the second buffer layer, the first active diode layer 507, the first buffer layer 505, and the first contact 503 may be patterned to form the layered structure of the desired laser diode 502. In an embodiment the second contact 511 and the ridge material 509 may be patterned using, e.g., a first photolithographic masking and etching process. Once the second contact 511 and the portion of the ridge material 509 have been patterned, the second buffer layer, the first active diode layer 507, and the first buffer layer 505 may be patterned using, e.g., a second photolithographic masking and etching process. Finally, the first contact 503 may be patterned using, e.g., a third photolithographic masking and etching process, to have an adiabatic taper to assist in evanescent coupling to underlying layers. However, any suitable patterning process, and any suitable number of patterning process may be utilized in order to obtain a desired pattern for the laser.

Once patterned, a second passivation layer 513 is deposited over the structure. In an embodiment the second passivation layer 513 is formed of a material used to electrically isolate and protect the structure from overlying structures, and may be a material such as silicon oxide, silicon nitride, silicon oxynitride, combinations of these, or the like, and may be deposited using a chemical vapor deposition process, an atomic layer deposition process, a physical vapor deposition process, combinations of these, or the like. However, any suitable materials and any suitable methods of deposition may be utilized.

After the second passivation layer 513 has been deposited, the second passivation layer 513 is patterned in order to form via openings through the second passivation layer 513 and expose the first contact 503 and the second contact 511. In an embodiment the patterning may be performed using, e.g., a photolithographic masking and etching process. However, any suitable patterning process may be utilized.

Once patterned, conductive extensions 515 may be formed to make contact with the second contact 511 and the first contact 503. In an embodiment the conductive extensions 515 may be a conductive material such as a metal like aluminum, copper, germanium, combinations of these, or the like, deposited using a deposition method such as plating, chemical vapor deposition, atomic vapor deposition, physical vapor deposition, combinations of these, or the like. However, any suitable material and method of manufacture may be utilized.

Once deposited, the conductive extensions 515 are pattered. In an embodiment in which the conductive extensions 515 are plated, the conductive extensions 515 may be patterned during the deposition process, while in other processes the conductive extensions 515 may be patterned after deposition using, for example, a photolithographic masking and etching process. However, any suitable process may be utilized.

After the conductive extensions 515 have been formed, a third passivation layer 517 is deposited over the conductive extensions 515. In an embodiment the third passivation layer 517 is a protective dielectric material such as silicon oxide, silicon nitride, silicon oxynitride, combinations of these, or the like, deposited using a deposition process such as chemical vapor deposition, atomic layer deposition, physical vapor deposition, combinations of these, or the like. However, any suitable materials and methods may be used to form the third passivation layer 517.

Once the third passivation layer 517 has been formed, multiple ones of the laser diodes 502 may be bonded to a first semiconductor substrate 519 with, e.g., a dielectric bonding layer 521 to form a reconstituted wafer. In an embodiment the first semiconductor substrate 519 may be a semiconductor material used for structural support during subsequent processing and as a heat sink to help with laser overheat issues, and may be, e.g., a silicon wafer, a silicon germanium wafer, a silicon-on-insulator wafer, or the like. In some embodiments the first semiconductor substrate 519 is a 12-inch wafer, with a second thickness T₂ of between about 20 μm and about 700 μm, although any suitable size and material may be utilized. The first semiconductor substrate 519 may be bonded using, e.g., a fusion bonding process, although any suitable processes may be utilized.

Once the attachment has occurred, the second substrate may be removed. In an embodiment the second substrate may be removed using a planarization process, such as a chemical mechanical polishing process, a grinding process, or the like. In other embodiments the second substrate may be removed using one or more etching processes in order to expose the third active layer 523. Any suitable method may be utilized.

Once the second substrate has been removed, a third active layer 523 of fourth optical components 525 may be bonded to the structure. In an embodiment the third active layer 523 of the third optical components 525 may be formed to receive and transmit optical signals generated by a laser diode 502. In an embodiment the third active layer 523 of the third optical components 525 may be formed on a separate substrate (not separately illustrated in FIG. 5) using similar materials and methods as the second active layer 207 of the second optical components 209, described above with respect to FIG. 2. However, any suitable methods and materials may be utilized.

The third active layer 523 additionally includes second mirrors 527 that will be utilized to redirect and transmit the optical signals generated by the laser diode 502. In an embodiment the second mirrors 527 may be formed using similar materials and methods as the first mirrors 211 described above with respect to FIG. 2. However, any suitable methods and materials may be utilized.

Once formed, the third active layer 523 may be bonded to the laser diode 502. In an embodiment the third active layer 523 may be bonded using a fusion bond with, e.g., an oxide layer, although any suitable material and method of bonding may be utilized. Once bonded, the separate substrate may be removed.

After the separate substrate has been removed, first through device vias 529 and a second bond layer 531 are formed. In an embodiment the first through device vias 529 extend through the third active layer 523 so as to provide a quick passage of power, data, and ground through the third active layer 523. In an embodiment the second through device vias 529 may be formed by initially forming through device via openings through the third active layer 523. The through device via openings may be formed by applying and developing a suitable photoresist (not shown), and removing portions of the third active layer 523 that are exposed.

Once the through device via openings have been formed, the through device via openings may be lined with a liner. The liner may be, e.g., an oxide formed from tetraethylorthosilicate (TEOS) or silicon nitride, although any suitable dielectric material may alternatively be used. The liner may be formed using a plasma enhanced chemical vapor deposition (PECVD) process, although other suitable processes, such as physical vapor deposition or a thermal process, may alternatively be used.

Once the liner has been formed along the sidewalls and bottom of the through device via openings, a barrier layer (also not independently illustrated) may be formed and the remainder of the through device via openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer (not shown), filling and overfilling the through device via openings. Once the through device via openings have been filled, excess liner, barrier layer, seed layer, and first conductive material outside of the through device via openings may be removed through a planarization process such as chemical mechanical polishing (CMP), although any suitable removal process may be used.

Once the second through device vias 529 have been formed, the second bond layer 531 may be formed. In an embodiment the second bond layer 531 comprises second bond pads 533 and a fifth dielectric 535 and may be formed using similar processes and materials as the first bond layer 415, the first bond pads 419 and the second dielectric material 417, described above with respect to FIG. 4. Once the second bond layer 531 has been formed, a combined thickness of the second bond layer 531 and the first dielectric material 411 over the first passivation layer 405 may be a first thickness T₁ of between about 0.8 μm and about 8 μm. However, any suitable processes and materials may be utilized.

In some embodiments the second bond pads 533 may be used not only for receiving and/or transmitting electrical signals. For example, in some embodiments, at least some of the second bond pads 533 may be dummy bond pads which are utilized for heat conduction or structure reasons, and are not functionally connected to a remainder of the circuitry, such as by being electrically isolated with dielectric material. However, any suitable use or number of the second bond pads 533 may be utilized.

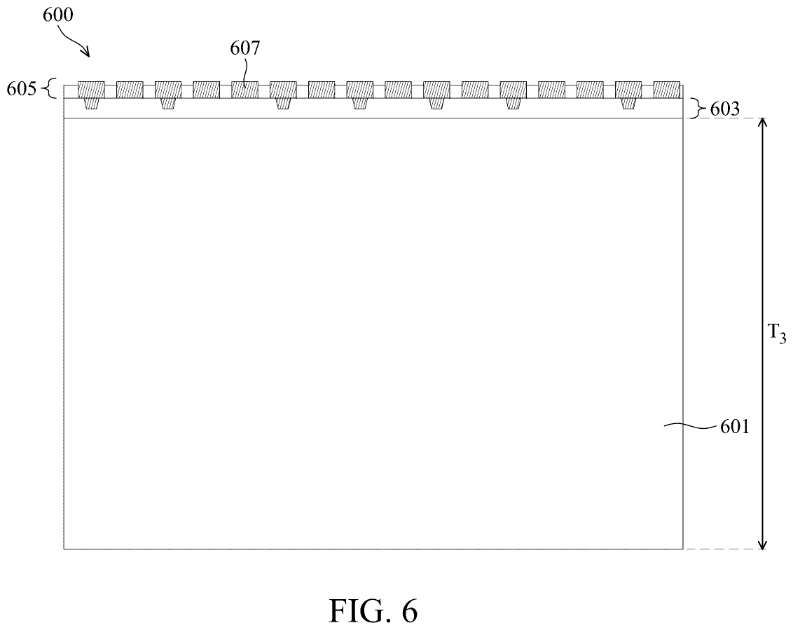

FIG. 6 illustrates a first semiconductor device 600 that will also be electrically connected to the optical interposer 400. In some embodiments, the first semiconductor device 600 is an electronic integrated circuit (EIC—e.g., a device without optical devices) and may have a second semiconductor substrate 601, a layer of active devices (not separately illustrated), an overlying interconnect structure 603, a third bond layer 605, and associated third bond pads 607. In an embodiment the second semiconductor substrate 601 may be similar to the first substrate 101 (e.g., a semiconductor material such as silicon or silicon germanium with a third thickness T₃ of between about 100 μm and about 650 μm), the active devices may be transistors, capacitors, resistors, and the like formed over the second semiconductor substrate 601, the interconnect structure 603 may be similar to the first metallization layers 401, the third bond layer 605 may be similar to the first bond layer 415, and the third bond pads 607 may be similar to the first bond pads 419. However, any suitable devices may be utilized.

In an embodiment the first semiconductor device 600 may be configured to work with the optical interposer 400 for a desired functionality. In some embodiments the first semiconductor device 600 may be a high bandwidth memory (HBM) module, an xPU, a logic die, a 3DIC die, a CPU, a GPU, a SoC die, a MEMS die, combinations of these, or the like. Any suitable device with any suitable functionality, may be used, and all such devices are fully intended to be included within the scope of the embodiments.

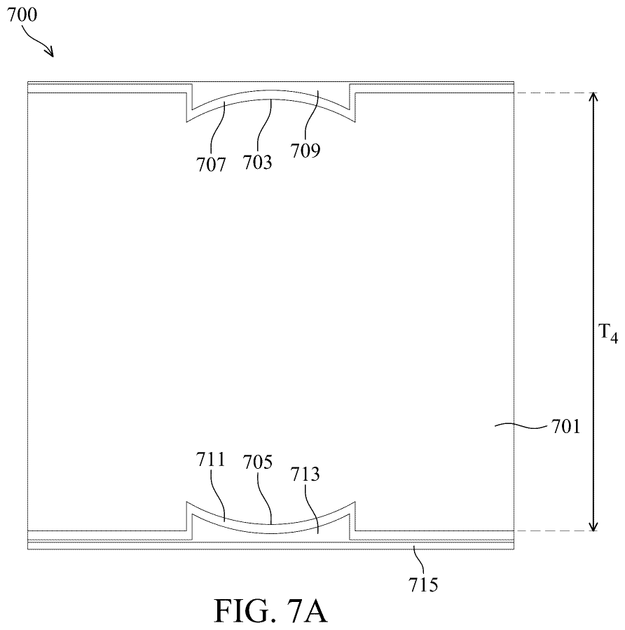

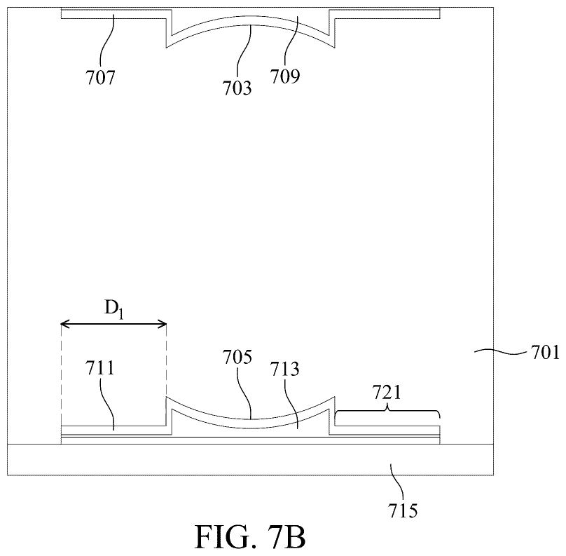

FIG. 7A illustrates an optional lens die 700 that will also be subsequently bonded to the optical interposer 400. In an embodiment the lens die 700 comprises a lens substrate 701 with a first lens 703 and a second lens 705 aligned with each other on opposite sides of the lens substrate 701. The lens substrate 701 may be a material that is transparent to the wavelength of light that is desired to be used, such as silicon, SiO₂, Al₂O₃, combinations of these, or the like. In an embodiment the lens substrate 701 has a fourth thickness T₄ of between about 100 μm and about 650 μm. However, any suitable material and dimensions may be utilized.

In an embodiment the first lens 703 may be formed by patterning the material of the lens substrate 701. In an embodiment the patterning may be performed using a photolithographic masking and etching process, whereby a photosensitive material is placed, exposed, developed, and reshaped in order to form a photomask, and the photomask is then used with one or more anisotropic etching process such as a reactive ion etch in order to etch into the material of the lens substrate 701.

FIG. 7A additionally illustrates formation of a first anti-reflective coating (ARC) 707 on the first lens 703. In an embodiment the first ARC 707 may be one or more layers of materials which help to prevent undesired reflections as light is focused and/or traverses through the first lens 703. In a particular embodiment the one or more layers of materials may be materials such as silicon oxide, silicon nitride, Ta₂O₅, MgF₂, composites of these, combinations of these, or the like, formed using processes such as chemical vapor deposition, atomic layer deposition, physical vapor deposition, oxidation, nitridation, combinations of these, or the like. Additionally, the first ARC 707 may be formed to have a thickness of between about 0.2 μm and about 2 μm. However, any suitable materials, thicknesses, and methods of deposition may be utilized.

In a particular embodiment the first ARC 707 may comprise multiples layers of material such as a first layer of silicon oxide and a first layer of silicon nitride formed over the first layer of silicon oxide. Additionally, in other embodiments a second layer of silicon oxide and a second layer of silicon nitride are be further deposited over the first layer of silicon oxide and the first layer of silicon nitride, thereby forming an alternating stack of silicon oxide and silicon nitride. However, any suitable combinations of materials may be utilized.

FIG. 7A additionally illustrates a deposition of a first fill material 709 to fill and/or overfill the recess formed by the first lens 703. In an embodiment the first fill material 709 may be a dielectric material such as silicon oxide, polyimide, combinations of these, or the like, deposited using a method such as chemical vapor deposition, physical vapor deposition, atomic layer deposition, combinations of these, or the like. However, any suitable material and any suitable method of deposition may be utilized.

Additionally, if desired, dopants may be added to the first fill material 709 in order to help adjust the desired properties of the first fill material 709. In one such embodiment in which the optical properties are desired to be modified, a dopant such as carbon, silicon, hydrogen, oxygen combinations of these, or the like, may be added to the oxide material of the first fill material 709 to a concentration of between about 0.1 at. % and about 95 at. %. However, any suitable dopant and any suitable concentration may be utilized.

Once deposited, a planarization process may be used to remove excess material from outside of the recess formed by the first lens 703. In an embodiment the planarization process may be performed using a chemical mechanical polishing process, whereby etchants and abrasives are used collectively with a grinding process in order to remove undesired material. However, any other suitable planarization process, such as a grinding process or even one or more etching processes, may also be utilized.

The second lens 705 may be formed on an opposite side of the lens substrate 701 from the first lens 703. Additionally, a second ARC 711 and a second fill material 713 may be deposited. The second lens 705, second ARC 711 and the second fill material 713 may be formed using similar materials and processes as the first lens 703, the first ARC 707, and the first fill material 709. However, any suitable materials and processes may be utilized.

FIG. 7A additionally illustrates formation of a fourth bonding layer 715 formed adjacent to the second lens 705. In an embodiment the third bonding layer 715 may comprise a bonding material suitable for fusion bonding, such as silicon oxide, silicon oxynitride, combinations of these, or the like, deposited using a deposition process such as chemical vapor deposition, physical vapor deposition, atomic layer deposition, combinations of these, or the like. However, any suitable material and any suitable processes may be utilized.

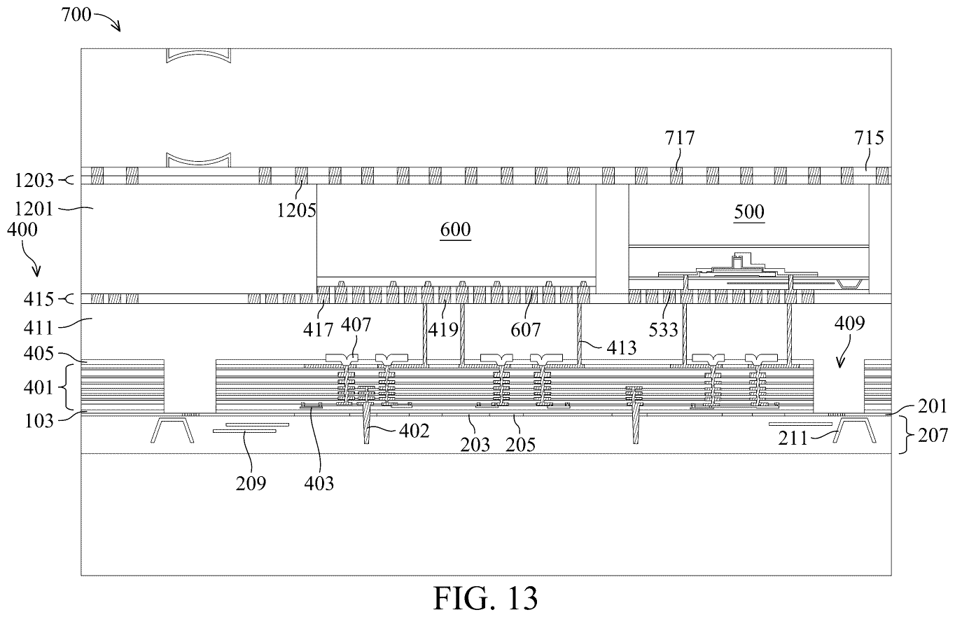

Optionally, while not illustrated in FIG. 7A but illustrated below with respect to FIG. 13, the fourth bonding layer 715 of the lens die 700 may additionally comprise lens bond pads 717 in order to enhance the bonding process and also to allow for additional heat dissipation, even without electrical transmission. In an embodiment the lens bond pads 717 may be formed using similar processes and materials as the first bond pads 419, described above with respect to FIG. 4. However, any suitable processes and materials may be utilized.

FIG. 7B illustrates another embodiment of the lens die 700. In this embodiments, however, instead of the first fill material 709 and the second fill material 713 being isolated in the recess above the first lens 703 and the second lens 705, optional side portions 721 are formed to extend away from the first lens 703 and the second lens 705. In this embodiment the side portions 721 may be formed by patterning the lens substrate 701 to form openings for the side portions 721 within the lens substrate 701 in addition to the formation of the first lens 703 and the second lens 705. Once the openings for the side portions 721 have been formed, the openings for the side portions 721 may be filled by the first ARC 707, the first fill material 709, the second ARC 711, and the second fill material 713, respectively.

In a particular embodiment the side portions 721 may be formed to provide a keep out region such that, once the lens die 700 is in place, no metal pads (e.g., the first bond pads 419) are located beneath the side portions 721 as well as not being located beneath the first lens 703 and the second lens 705. For example, the side portions 721 may extend a distance away from the first lens 703 and the second lens 705 a first distance D₁ of less than about 10 μm. However, any suitable distance may be utilized.

FIG. 8 illustrates a bonding of the laser die 500, the first semiconductor device 600, and the lens die 700 to the optical interposer 400. In a particular embodiment the laser die 500 and the first semiconductor device 600 may be bonded using a dielectric-to-dielectric and metal-to-metal bonding process. In a particular embodiment which utilizes the dielectric-to-dielectric and metal-to-metal bonding process, the process may be initiated by activating the surfaces of the laser die 500 (e.g., the second bond layer 531), the first semiconductor device 600 (e.g., the third bond layer 605), and the surfaces of the first bonding layer 415. Activating the top surfaces of the first bonding layer 415, the second bond layer 531, and the third bond layer 605 may comprise a dry treatment, a wet treatment, a plasma treatment, exposure to an inert gas plasma, exposure to H₂, exposure to N₂, exposure to O₂, combinations thereof, or the like, as examples. In embodiments where a wet treatment is used, an RCA cleaning may be used, for example. In another embodiment, the activation process may comprise other types of treatments. The activation process assists in the bonding of the first bonding layer 415, the second bond layer 531, and the third bond layer 605.

After the activation process the optical interposer 400, the first semiconductor device 600 and the laser die 500 may be cleaned using, e.g., a chemical rinse, and then the first semiconductor device 600 and laser die 500 are aligned and placed into physical contact with the optical interposer 400. The optical interposer 400, the laser die 500, and the first semiconductor device 600 are then subjected to thermal treatment and contact pressure to bond the optical interposer 400, the first semiconductor device 600, and the laser die 500. For example, the optical interposer 400, the laser die 500, and the first semiconductor device 600 may be subjected to a pressure of about 200 kPa or less, and a temperature between about 25° C. and about 250° C. to fuse the optical interposer 400, the laser die 500, and the first semiconductor device 600. The optical interposer 400, the laser die 500, and the first semiconductor device 600 may then be subjected to a temperature at or above the eutectic point for material of the first bond pads 419, the second bond pads 533, and the third bond pads 607, e.g., between about 150° C. and about 650° C., to fuse the metal. In this manner, the optical interposer 400, the laser die 500, and the first semiconductor device 600 form dielectric-to-dielectric and metal-to-metal bonds. In some embodiments, the bonded dies are subsequently baked, annealed, pressed, or otherwise treated to strengthen or finalize the bond.

Additionally, while specific processes have been described to initiate and strengthen the bonds, these descriptions are intended to be illustrative and are not intended to be limiting upon the embodiments. Rather, any suitable combination of baking, annealing, pressing, or combination of processes may be utilized. All such processes are fully intended to be included within the scope of the embodiments.

Further, while a dielectric-to-dielectric and metal-to-metal bonding process is described above as one embodiment, this is intended to be illustrative and is not intended to limit the embodiments. Rather, any suitable bonding processes, such as integrated fan out (InFO) processes, chip-on-wafer-on-substrate (CoWoS) processes, and flip chip technologies, may also be used. All such processes and combination of processes are fully intended to be included within the scope of the embodiments.

FIG. 8 additionally illustrates that the lens die 700 is bonded to the optical interposer 400. In an embodiment the lens die 700 may be bonded to the optical interposer 400 using, e.g., a fusion bonding process whereby the fourth bonding layer 715 is bonded to dielectric material of the first bonding layer 415. In a particular embodiment the fusion bonding process may be similar to the dielectric-to-dielectric and metal-to-metal bonding process described above, except without the bonding of the metal components. However, any suitable bonding process may be utilized.

Finally, while a single laser die 500, a single first semiconductor device 600 and a single lens die 700 are illustrated in FIG. 8, this is intended to be illustrative and is not intended to limit the embodiments. Rather, any suitable number of laser dies 500, any suitable number of first semiconductor devices 600 (with any suitable functionality), and any suitable number of lens dies 700 may be utilized. All such combinations are fully intended to be included within the scope of the embodiments.

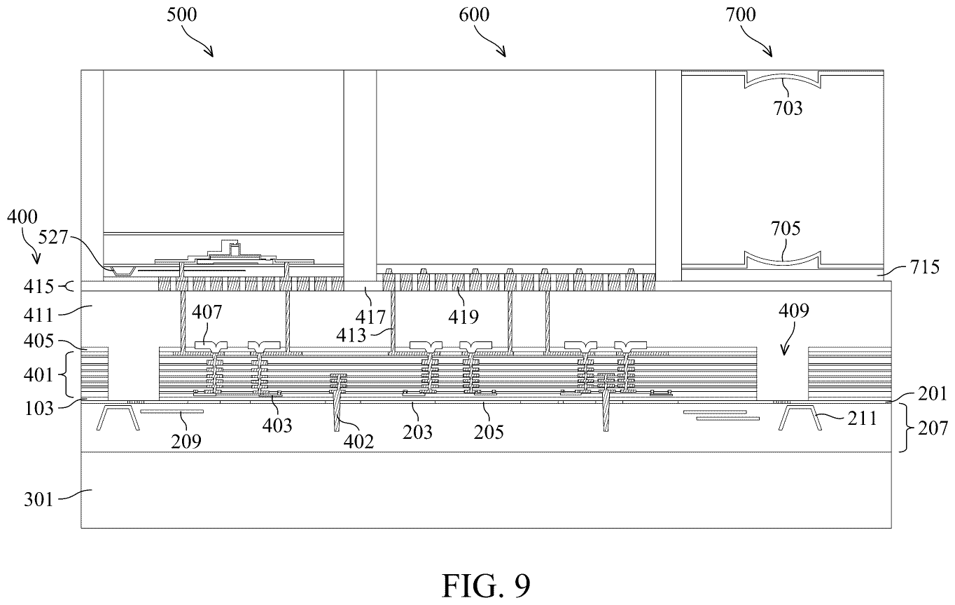

FIG. 9 illustrates an encapsulation of the laser die 500, the first semiconductor device 600 and the lens die 700 with an encapsulant 901. In an embodiment the encapsulant 901 may be a material such as a molding compound placed using an injection molding process. Once in place, the molding compound may be cured and planarized. However, any suitable material and process may be used.

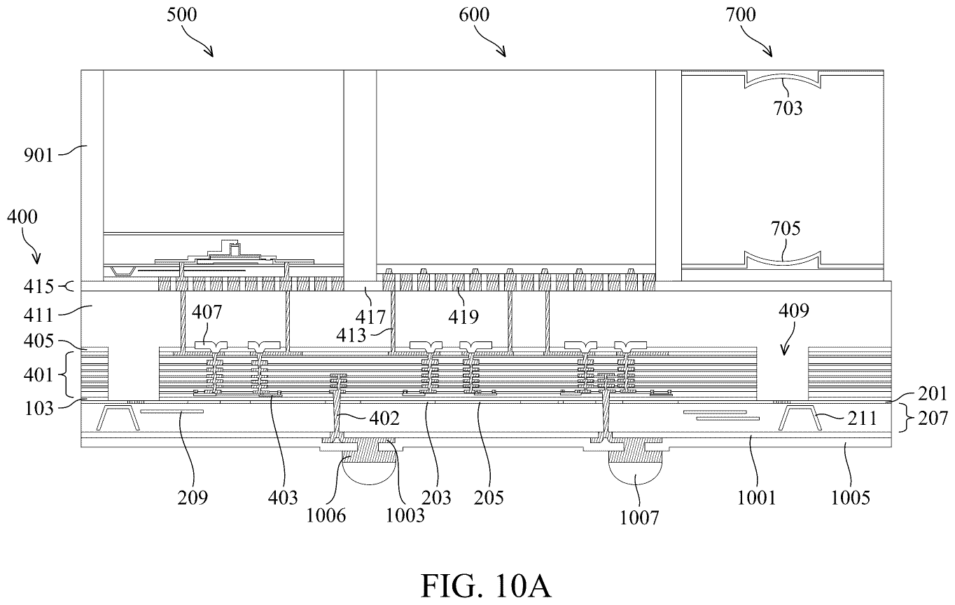

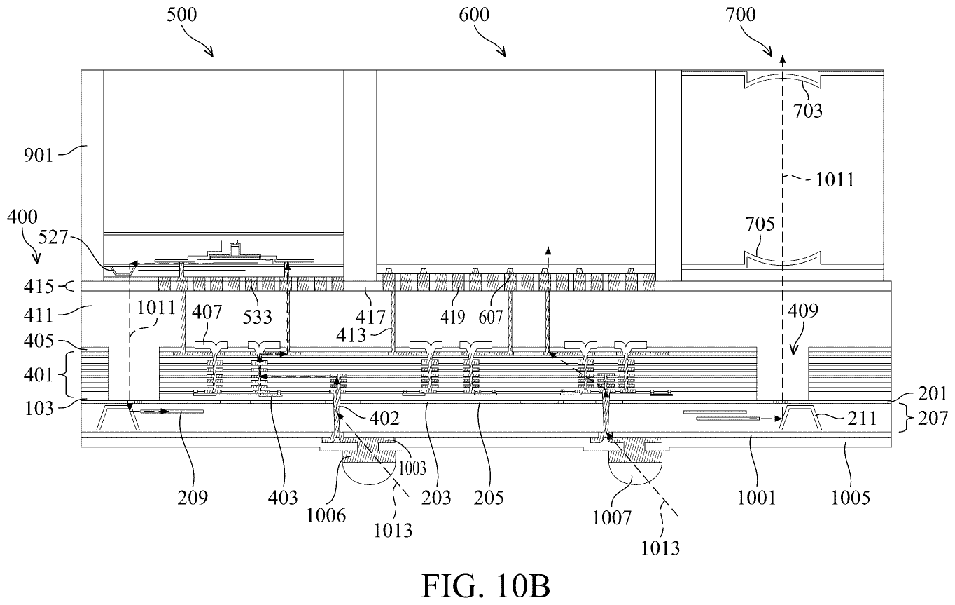

FIG. 10A illustrates a removal of the carrier substrate 301 and a thinning of the second active layer 207 to expose the first through device vias 402. In an embodiment the removal of the carrier substrate 301 and the thinning of the second active layer 207 may be performed using a planarization process such as a chemical mechanical polishing process or a grinding process. However, any suitable process may be utilized.

FIG. 10A additionally illustrates formation of a fourth passivation layer 1001, first redistribution layer 1003, a fifth passivation layer 1005, first underbump metallizations 1006, and first external connectors 1007. In an embodiment the fourth passivation layer 1001, the first redistribution layer 1003, and the fifth passivation layer 1005, may be formed using similar materials and processes as the second passivation layer 513, the first metallization layers 401, and the second passivation layer 513, respectfully. However, any suitable materials and processes may be utilized.

FIG. 10A additionally illustrates formation of the first underbump metallizations 1006 and a placement of the first external connectors 1007 which may be formed to provide conductive regions for contact between the first redistribution layer 1003 to other external devices. In an embodiment the first underbump metallizations 1006 may comprise three layers of conductive materials, such as a layer of titanium, a layer of copper, and a layer of nickel (with only a single material being illustrated in FIG. 10A for clarity, but not limited thereto). However, one of ordinary skill in the art will recognize that there are many suitable arrangements of materials and layers, such as an arrangement of chrome/chrome-copper alloy/copper/gold, an arrangement of titanium/titanium tungsten/copper, or an arrangement of copper/nickel/gold, that are suitable for the formation of the first underbump metallizations 1006. Any suitable materials or layers of material that may be used for the first underbump metallizations 1006 are fully intended to be included within the scope of the embodiments. In an embodiment the first underbump metallizations 1006 are created by forming each layer using a plating process, such as electrochemical plating, although other processes of formation, such as sputtering, evaporation, or PECVD process, may be used depending upon the desired materials.

The first external connectors 1007 may be conductive bumps (e.g., C4 bumps, ball grid arrays, microbumps, etc.) or conductive pillars utilizing materials such as solder and copper. In an embodiment in which the first external connectors 1007 are contact bumps, the first external connectors 1007 may comprise a material such as tin, or other suitable materials, such as silver, lead-free tin, or copper. In an embodiment in which the first external connectors 1007 are tin solder bumps, the first external connectors 1007 may be formed by initially forming a layer of tin through such commonly used methods such as evaporation, electroplating, printing, solder transfer, ball placement, etc. Once a layer of tin has been formed on the structure, a reflow may be performed in order to shape the material into the desired bump shape.

Of course, while the use of first external connectors 1007 is one embodiment which may be used in order to provide connections for the optical interposer 400, this is intended to be illustrative and is not intended to limit the embodiments. Rather, any suitable method of physically, electrically, and in some cases optically connecting the optical interposer 400, such as dielectric-to-dielectric and metal-to-metal bonding, may also be utilized. Any suitable method of bonding the optical interposer 400 may be used.

FIG. 10B illustrates movement of optical signals (represented by arrows labeled 1011) and electrical signals (represented by arrows labeled 1013) through the various devices during operation. In one embodiment an optical signal 1011 is generated by the laser die 500 and routed to the second mirrors 527, which redirects the optical signal 1011 from the laser die 500 through the first openings 409 and to a grating coupler (one of the first optical components 203 within the first active layer 201) and the first mirror 211. The first mirror 211 then redirects the optical signals 1011 from the laser die 500 into the second optical components 209 and, from there, to other parts of the device such as the first optical components 203 within the first active layer 201 and to the third optical components 403 (e.g., an optical to electrical converter) within the first metallization layers 401.

Similarly, for optical signals 1011 that are desired to be transmitted from the optical interposer 400, the optical interposer 400 generates the optical signals 1011 (using, e.g., an electrical to optical converter within the third optical components 403 within the first metallization layers 401) and then route the optical signals 1011 to the second optical components 209 and to the first mirror 211 located beneath the lens die 700. The first mirror 211 then redirects the optical signals 1011 through the first openings 409 and to the second lens 705 and the first lens 703 within the lens die 700, from which is can be directed into or out of the overall device through, e.g., an optical fiber (not separately illustrated).

For electrical signals 1013, the optical interposer 400 may supply electrical signals to both the laser die 500 and the first semiconductor device 600. For example, for the laser die 500, the electrical signals 1013 may be transmitted through the first external connectors 1007 to the first metallization layers 401 to the through dielectric vias 413, and then into the second bond pads 533. Similarly, for the first semiconductor device 600, the electrical signals 1013 may be transmitted through the first external connectors 1007 to the first metallization layers 401 to the through dielectric vias 413, and then into the third bond pads 607.

Additionally, if desired, the first optical components 203 and the third optical components 403 may be utilized to convert optical signals 1011 to electrical signals 1013 and vice versa. For example, in some embodiments the optical signals 1011 may be converted to electrical signals 1013 and transmitted to the first semiconductor device 600 for processing. Similarly, electrical signals 1013 may be transmitted from the first semiconductor device 600 to the first optical components 203 and the third optical components 403 and converted to optical signals 1011 for, for example, transmission out of the device. However, any suitable conversion and any other suitable modulation may be used, and all such actions are fully intended to be included within the scope of the embodiments.

By utilizing dielectric-to-dielectric and metal-to-metal bonding processes, the bump pitch and density can be increased while using a low-cost integration process. Additionally, by integrating the laser die 500, there is no need for the use of other silicon substrates to provide extra optical signal transfer paths, leading to shorted optical paths and lower optical transmission losses and a simplified, less expensive process flow. Finally, without the use of devices such as support substrates overlying the laser die 500 and the first semiconductor device 600, there are no dielectric interfaces within the thermal dissipation path, thereby improving the thermal dissipation. All of this allows for an overall more efficient device.

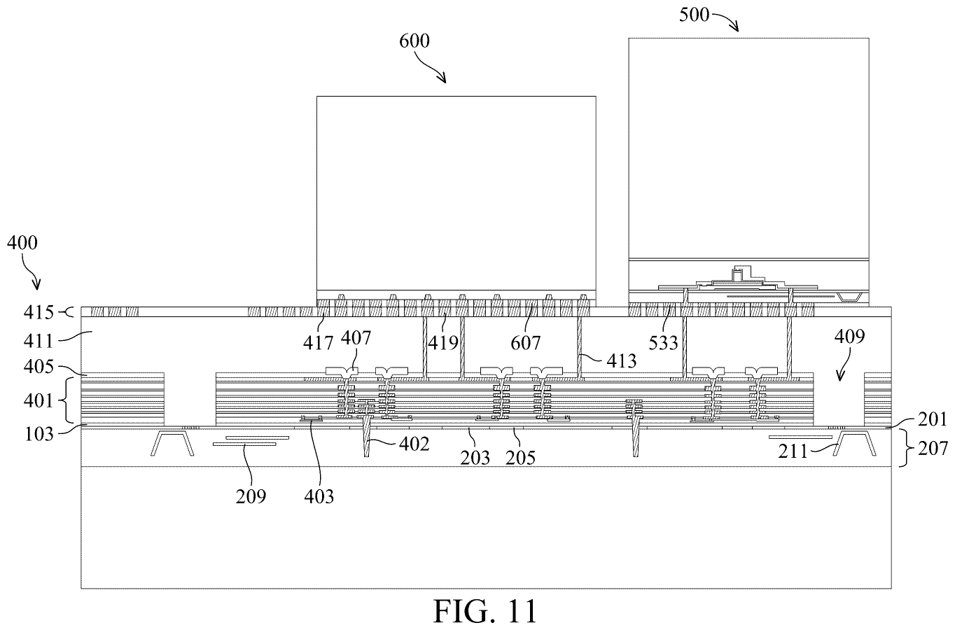

FIGS. 11-14 illustrate another embodiment in which the lens die 700, instead of being bonded to the optical interposer 400 as described above, is instead bonded to the first semiconductor device 600 and the laser die 500 after the laser die 500 and the first semiconductor device 600 have been bonded to the optical interposer 400. In this embodiment, and as illustrated in FIG. 11, the laser die 500 and the first semiconductor device 600 may be bonded to the optical interposer 400 as described above with respect to FIG. 8. For example, the laser die 500 and the first semiconductor device 600 may be bonded using a dielectric-to-dielectric and metal-to-metal bonding process. However, any suitable bonding process may be utilized.

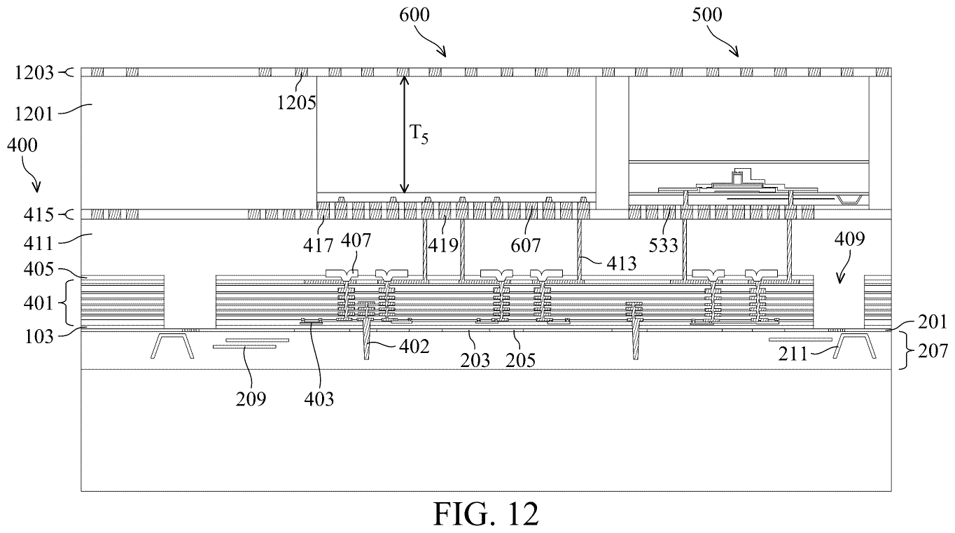

FIG. 12 illustrates that, once the laser die 500 and the first semiconductor device 600 have been bonded, the laser die 500 and the first semiconductor device 600 may be planarized to thin down the substrates and have a similar height, wherein the second semiconductor substrate 601 may have a fifth thickness T₅ of between about 20 μm to about 200 μm. In an embodiment the laser die 500 and the first semiconductor device 600 may be planarized using, e.g., a planarization process such as a chemical mechanical polishing process, a grinding process, combinations of these, or the like. However, any suitable planarization process may be utilized.

Once the laser die 500 and the first semiconductor device 600 have been bonded, a first gap fill material 1201 may be deposited in order to fill the spaces between and around the laser die 500 and the first semiconductor device 600. In an embodiment the first gap-fill material 1201 may be a material such as silicon oxide, silicon nitride, silicon oxynitride, combinations of these, or the like, deposited to fill and overfill the spaces around the first semiconductor device 600 and the laser die 500. However, any suitable material and method of deposition may be utilized.

Once the first gap-fill material 1201 has been deposited, the first gap-fill material 1201 may be planarized in order to expose the first semiconductor device 600 and the laser die 500. In an embodiment the planarization process may be a chemical mechanical planarization process, a grinding process, or the like. However, any suitable planarization process may be utilized.

FIG. 12 additionally illustrates a formation of a fifth bond layer 1203 with optional fourth bond pads 1205 over the first semiconductor device 600, the laser die 500, and the first gap-fill material 1201. In an embodiment the fourth bond layer 1203 and the lens bond pads 717 may be formed using similar processes and materials as the first bonding layer 415 and the first bond pads 419, described above with respect to FIG. 4. However, any suitable processes may be utilized.

FIG. 13 illustrates a bonding of the lens die 700 to the fifth bond layer 1203. In an embodiment the lens die 700 may be bonded to the fourth bond layer 1203 using, e.g., a fusion bond process (as described above with respect to FIG. 8) or else, if the optional lens bond pads 717 are present, using a dielectric-to-dielectric and metal-to-metal bond process (as described above with respect to FIG. 8). However, any suitable bonding process may be utilized.

In this embodiment, however, the lens die 700 may be used to provide additional structural support to the overall device. As such, the lens die 700 may extend the width of the optical interposer 400 and extend over each of the first semiconductor device 600, the laser die 500, and the first gap-fill material 1201. However, any suitable dimensions may be utilized.

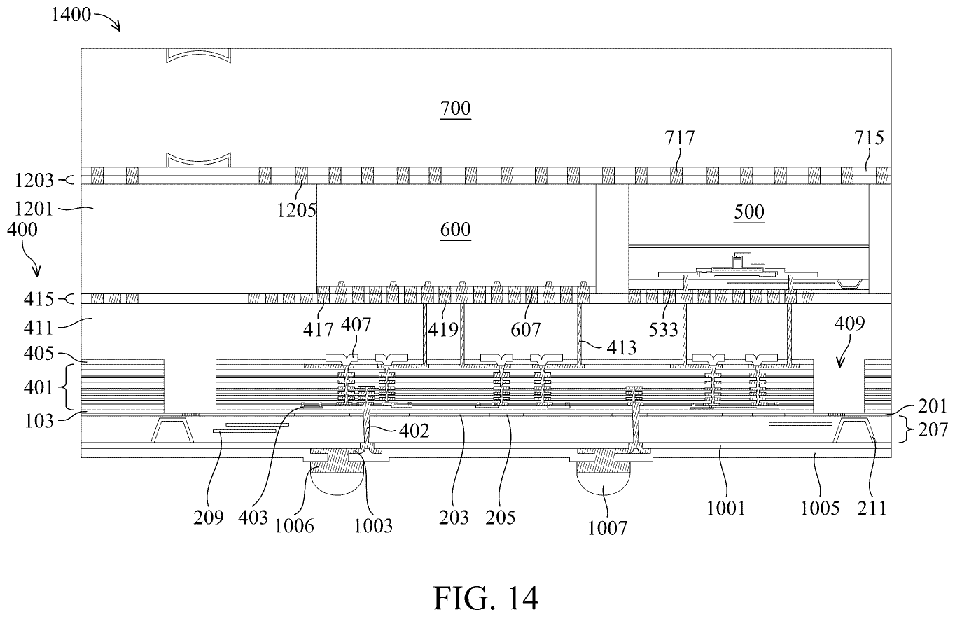

FIG. 14 illustrates that, once the lens die 700 has been bonded, the process may proceed as described above in FIG. 10A. For example, the carrier substrate 301 may be removed, the first through device vias 402 may be revealed by thinning, and the fourth passivation layer 1001, the first redistribution layer 1003, the fifth passivation layer 1005, the first underbump metallizations 1006 and the first external connectors 1007 may be formed. However, any suitable processes and structures may be utilized.

Finally, once the first external connectors 1007 have been formed, the structure may be singulated to form a first integrated device 1400. In an embodiment the structure may be singulated using, e.g., a saw blade to cut through the structure, such that the sidewalls of the lens die 700 and the optical interposer 400 are coplanar. However, any other suitable singulation process, such as a series of etching processes, or even a combination of sawing and etching, may be also be utilized.

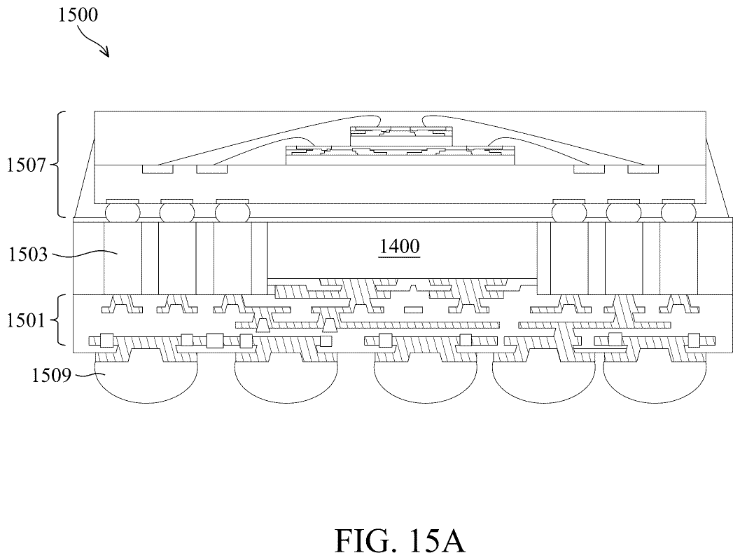

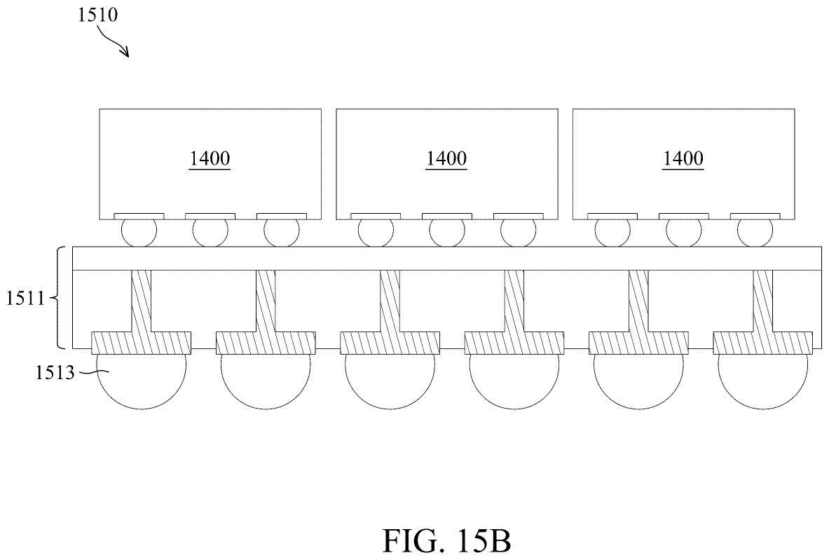

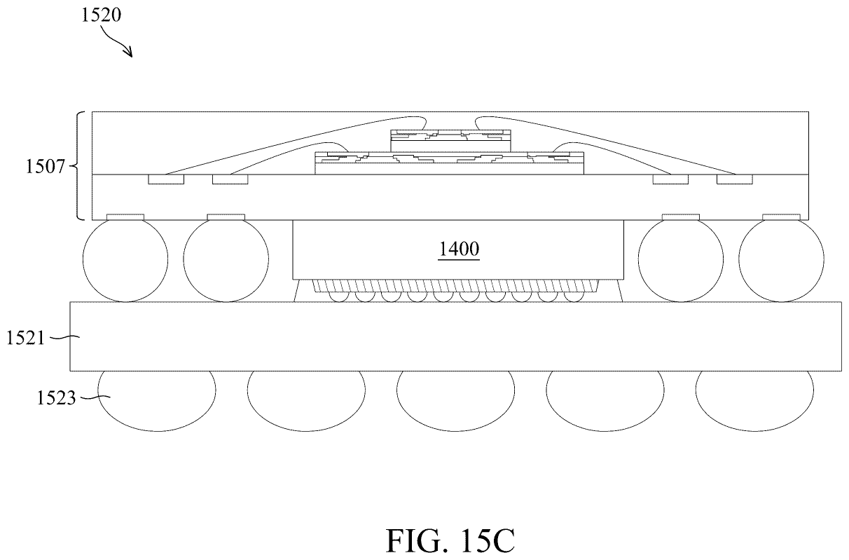

FIGS. 15A-15C illustrate that the processes and devices such as the first integrated device 1400 described above can be utilized in a wide variety of different packages to achieve improved performance. For example, as illustrated in FIG. 15A, the devices may be integrated into an integrated fan out (InFO) package 1500. For example, a series of metallization layers 1501 may be formed, through vias 1503 (e.g., copper vias) may be formed, the first integrated device 1400 may be placed (using, e.g., a dielectric-to-dielectric and metal-to-metal bond) and encapsulated with the through vias 1503, a memory device 1507 comprising a substrate and multiple memory dies (e.g., DRAM dies) wire bonded to the substrate is placed, and external connectors 1509 such as a ball grid array are placed.

FIG. 15B illustrates another device in which the first integrated device 1400 is incorporated into a chip-on-wafer-on-substrate (CoWoS) package 1510. In this embodiment one or more of the integrated devices 1505 may be bonded to a redistribution layer interposer 1511, and external connectors 1513 such as copper microbumps are placed.

FIG. 15C illustrates yet another device in which the first integrated device 1400 is incorporated into a flip chip package 1520. In this embodiment one or more of the first integrated device 1400 are bonded to a substrate 1521, and the memory device 1507 is also bonded to the substrate 1521. External connectors 1523 such as a ball grid array are then placed on the substrate 1521.

By utilizing dielectric-to-dielectric and metal-to-metal bonding processes, the bump pitch and density between devices can be increased while using a low-cost integration process. Additionally, by integrating the laser die 500, there is no need for the use of other silicon substrates to provide extra optical signal transfer paths, leading to shorted optical paths and lower optical transmission losses and a simplified, less expensive process flow. Finally, without the use of devices such as support substrates overlying the laser die 500 and the first semiconductor device 600, there are no dielectric interfaces within the thermal dissipation path, thereby improving the thermal dissipation. All of this allows for an overall more efficient device.

In an embodiment, a method of manufacturing an optical device includes: forming metallization layers over a first active layer of first optical components; forming a first opening through the metallization layers; bonding a first semiconductor die over the metallization layers; and bonding a laser die over the metallization layers, wherein after the bonding the laser die a first mirror located within the laser die is aligned with a second mirror through the first opening. In an embodiment the method further includes bonding a lens die over the metallization layers, wherein after the bonding the lens die the lens die comprises a first lens aligned with a third mirror through a second opening through the metallization layers. In an embodiment the method further includes depositing a gap fill material around the first semiconductor die and the laser die. In an embodiment the method further includes bonding a lens die to the gap fill material, wherein after the bonding the lens die the lens die comprises a first lens aligned with a third mirror through a second opening through the metallization layers. In an embodiment the method further includes forming the second mirror prior to the bonding the laser die. In an embodiment the method further includes thinning the first semiconductor die and the laser die after the bonding the first semiconductor die and the bonding the laser die. In an embodiment the bonding the first semiconductor die is performed with a dielectric-to-dielectric and metal-to-metal bonding process.

In another embodiment, a method of manufacturing an optical device includes: forming a first active layer of first optical components; forming a second active layer of second optical components, the second optical components comprising a first mirror and a second mirror; forming a first metallization layer on an opposite side of the first active layer from the second active layer; forming a first opening through the first metallization layer over the first mirror; forming a second opening through the first metallization layer over the second mirror; filling the first opening and the second opening; bonding a laser die over the first opening and to a first surface; and bonding a first semiconductor die to the first surface. In an embodiment the method further includes bonding a lens die over the second opening and to the first surface. In an embodiment the method further includes depositing a gap fill material around the laser die and the first semiconductor die. In an embodiment the method further includes bonding a lens die over the second opening and over the gap fill material. In an embodiment the bonding the lens die is performed with a fusion bonding process. In an embodiment the bonding the lens die is performed with a dielectric-to-dielectric and metal-to-metal bonding process. In an embodiment the forming the first opening exposes a grating coupler of the first optical components.

In yet another embodiment an optical device includes: metallization layers over a first active layer of first optical components; a first opening through the metallization layers; a first semiconductor die bonded over the metallization layers; and a laser die bonded over the metallization layers, wherein a first mirror located within the laser die is aligned with a second mirror through the first opening. In an embodiment the optical device further includes a lens die bonded over the metallization layers. In an embodiment the optical device further includes a gap fill material surrounding the first semiconductor die and the laser die. In an embodiment the optical device further includes a lens die bonded over the gap fill material. In an embodiment the lens die is bonded with a dielectric-to-dielectric and metal-to-metal bond. In an embodiment a first lens within the lens die and a second lens within the lens die is aligned with a third mirror through a second opening through the metallization layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An optical device comprising:
metallization layers over a first active layer of first optical components;
a first opening through the metallization layers;
a first semiconductor device electrically connected to the metallization layers; and
a laser die electrically connected to the metallization layers, wherein a first mirror located in the laser die is aligned with a second mirror through the first opening, the second mirror being aligned with second optical components optically connected to the first optical components.

2. The optical device of claim 1, further comprising silicon oxide filling the first opening.

3. The optical device of claim 2, wherein the silicon oxide extends over the metallization layers.

4. The optical device of claim 3, wherein the silicon oxide fills a second opening through the metallization layers.

5. The optical device of claim 4, further comprising a lens die, wherein a lens within the lens die is aligned with a third mirror through the second opening.

6. The optical device of claim 5, wherein the lens die is bonded to the laser die.

7. The optical device of claim 5, wherein the lens die is bonded to the metallization layers.

8. An optical device comprising:
a first active layer of first optical components;
a second active layer of second optical components, the second optical components comprising a first mirror and a second mirror;
a first metallization layer on an opposite side of the first active layer from the second active layer;
a first opening through the first metallization layer over the first mirror;
a second opening through the first metallization layer over the second mirror;
a laser die bonded to a first surface, the laser die being located over the first opening; and
a first semiconductor device bonded to the first surface.

9. The optical device of claim 8, further comprising a first material filling both the first opening and the second opening.

10. The optical device of claim 9, wherein the first material extends over the first metallization layer.

11. The optical device of claim 10, wherein the first material is silicon oxide.

12. The optical device of claim 11, further comprising vias extending through the silicon oxide to the first metallization layer.

13. The optical device of claim 8, further comprising a lens die, the lens die comprising a lens located over the second opening.

14. The optical device of claim 13, wherein the lens die is bonded to the first surface.

15. An optical device comprising:
a laser die comprising a first output;
a first mirror aligned with the first output through a first opening in a first metallization layer, the first mirror being located in a first layer;
a first layer of optical components between the first layer and the laser die;
a second mirror located in the first layer; and
a lens die comprising a first lens aligned with the second mirror through a second opening in the first metallization layer.

16. The optical device of claim 15, wherein the lens die overlies the laser die.

17. The optical device of claim 15, wherein the lens die has a top surface aligned with a top surface of the laser die.

18. The optical device of claim 15, further comprising a semiconductor die adjacent to the laser die.

19. The optical device of claim 15, wherein the laser die is bonded to a bonding layer overlying a dielectric material filling the first opening and the second opening.

20. The optical device of claim 19, wherein the dielectric material covers the first metallization layer.
